(19) United States
(12) Patent Application Publication
(10) Pub. No.: US 2012/0081141 A1
(43) Pub. Date: Apr. 5, 2012

(54) On-Chip Delay Measurement Through a Transistor Array

(75) Inventors: Keith A. Jenkins, Sleepy Hollow, NY (US); Jae-Joon Kim, Yorktown Heights, NY (US); Rahul M. Rao, Austin, TX (US)

(73) Assignee: INTERNATIONAL BUSINESS MACHINES CORPORATION, Armonk, NY (US)

(21) Appl. No.: 12/894,334

(22) Filed: Sep. 30, 2010

(51) Int. Cl. G01R 31/26

(52) U.S. Cl. 324/762.01

(57) ABSTRACT

Methods and apparatus are provided for measuring a delay through one or more transistors in an array of transistors. The delay through one or more transistors in an array of transistors is measured by selecting one of the transistors in the array; and applying a clock signal to the selected transistor, wherein an output of the selected transistor is applied to a first input of a logic gate having at least two inputs and wherein a second clock signal based on the clock signal is applied to a second input of the logic gate, and wherein an output of the logic gate indicates a difference in arrival times of the signals at the two inputs. In one variation, a clock signal is applied to the selected transistor and a variable delay circuit; and an output of the selected transistor is applied to a data input of a latch having a clock input and a data input while an output of the variable delay circuit is applied to a clock input of the latch. The delay applied by the variable delay circuit to the clock signal is adjusted until a predefined transition is detected in an output of the latch. If the delay is measured through a plurality of transistors in the array, the delay variation among the plurality of transistors can be obtained.

### FIELD OF THE INVENTION

The present invention relates generally to delay measurement techniques for transistor circuits, and more particularly, to digital techniques for measuring a delay through one or more transistors in an array of transistors.

### BACKGROUND OF THE INVENTION

The time delay through an electrical circuit varies significantly due to a number of factors, including aging and variations in the manufacturing process (P), power supply voltage (V) and operating temperature (T), often collectively referred to as PVT variations. The “process” component of a transistor refers to the process of manufacturing the transistor and is typically classified as “fast,” “slow,” “nominal,” or some intermediate value. Once a transistor is manufactured using a particular process, the effect of the process component is fixed.

The “temperature” component of a transistor is the temperature at which the transistor operates. The rate at which a transistor transmits a signal is affected by the temperature at which the transistor is operating. Generally, as the temperature of a transistor decreases, the voltage required to transmit signals at the same rate also decreases. Likewise, as the temperature of a transistor increases, the voltage required to transmit signals at the same rate also increases. The “voltage” component is the only component that can be varied during operation to adjust a transistor's characteristics.

It is well known that sub-micron CMOS transistors (FETs) show random variability of their threshold voltage and output currents due to manufacturing and/or process variations. This is apparent from DC measurements of currents in devices that are intended to be identical, such as the transistors in an array of transistors. There is also a concern, however, that there might be variability of the switching delay of these devices (often referred to as “AC variability”) that is greater than that expected from measured DC variability.

A need therefore exists for a direct method to measure such AC variability of individual devices. A further need exists for methods and circuits that measure a delay through one or more transistors in an array of transistors.

### SUMMARY OF THE INVENTION

Generally, methods and apparatus are provided for measuring a delay through one or more transistors in an array of transistors. According to one aspect of the invention, the delay through one or more transistors in an array of transistors is measured by selecting one of the transistors in the array; and applying a clock signal to the selected transistor, wherein an output of the selected transistor is applied to a first input of a logic gate having at least two inputs and wherein a second clock signal based on the clock signal is applied to a second input of the logic gate, and wherein an output of the logic gate indicates a difference in arrival times of the signals at the two inputs.

The selection may comprise, for example, asserting an appropriate select line signal. The output of the logic gate indicates a difference in arrival times of the signals at the two inputs. If the delay is measured through a plurality of transistors in the array, the delay variation among the plurality of transistors can be obtained.

According to another aspect of the invention, the delay through one or more transistors in an array of transistors is measured by selecting one of the transistors in the array; applying a clock signal to the selected transistor and a variable delay circuit; applying an output of the selected transistor to a data input of a latch having a clock input and a data input; applying an output of the variable delay circuit to a clock input of the latch; and adjusting a delay applied by the variable delay method to the clock signal until a predefined transition is detected in an output of the latch.

A more complete understanding of the present invention, as well as further features and advantages of the present invention, will be obtained by reference to the following detailed description and drawings.

### BRIEF DESCRIPTION OF THE DRAWINGS

FIG. 1 illustrates a circuit for measuring a delay through a transistor array, in accordance with an embodiment of the present invention;

FIG. 2 illustrates the various signals shown in FIG. 1;

FIG. 3 illustrates a circuit for measuring a delay through a transistor array, in accordance with an alternate embodiment of the present invention;

FIGS. 4A and 4B illustrate the various signals shown in FIG. 3 at different times; and

FIGS. 5 through 8 illustrate various alternative designs for the device under test (DUT) array of FIG. 1.

### DETAILED DESCRIPTION OF PREFERRED EMBODIMENTS

The present invention provides methods and circuits that measure a delay through one or more transistors in an array of transistors. The present invention measures the AC variability of FETs by directly or indirectly measuring a signal delay through a single element of an array of active transistors or gates. The transistors are nominally identical, so the variation of the delay gives a measure of their AC variability, which may be in accordance with the DC variability, or may be greater. The exemplary circuit is designed for on-chip measurements, so no connections to devices to be measured need to be made or broken. As discussed further below, the invention provides a means for selecting the individual transistors or gates to be measured, and methods of directly and indirectly measuring the delays through the individual transistors or gates.

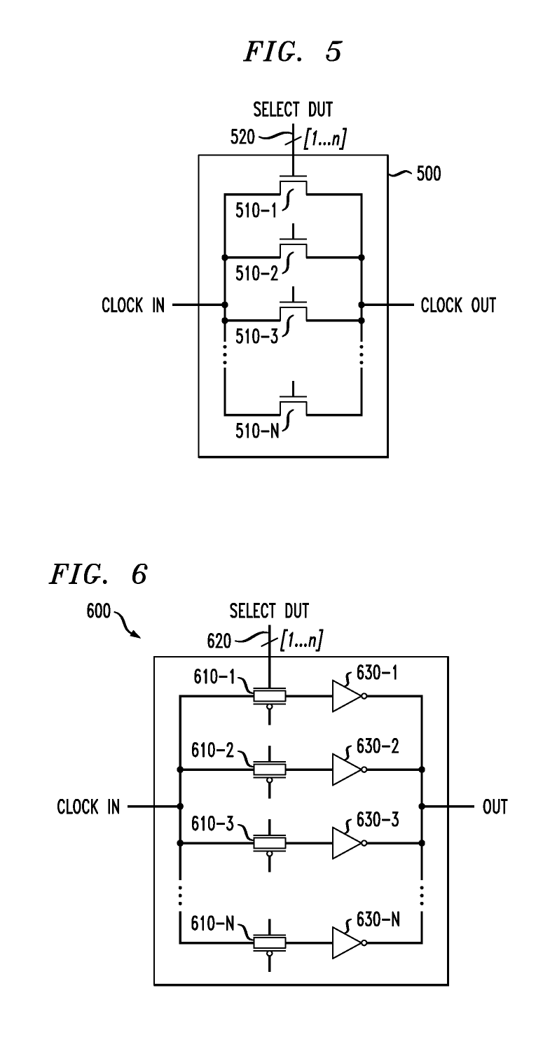

FIG. 1 illustrates a circuit 100 for measuring a delay through one or more transistors 110-1 through 110-4 in an array of transistors (collectively, referred to as array) 10), in accordance with an embodiment of the present invention. In the exemplary embodiment of FIG. 1, each gate or DUT comprises an NFET transistor and a PFET transistor connected to form a transmission gate. The exemplary circuit 100 comprises a selection circuit 120 for selecting one of the transmission gates 110-i to be active in the array 110, by asserting an appropriate select line signal. The select line signal can be derived, for example, from a finite state machine or a scan chain. The array 110 is a DUT (“Device Under Test”) array of n transmission gates. Alternative DUT arrays 110 are discussed further below in conjunction with FIGS. 5-8.

In addition, the exemplary circuit 100 includes a logic gate 140 having at least two inputs. The logic gate 140 may be embodied, for example, as a NAND gate, as shown in the exemplary embodiment of FIG. 1.

A clock signal source 105, such as an external clock source or an on-chip oscillator, applies a clock signal to the transistor 110-i that is selected by the selection circuit 120.

As shown in FIG. 1, an output of the selected transmission gate 110-i is applied to a first input of the logic gate 140. In addition, as shown in FIG. 1, a second clock signal, based on the clock signal, is applied to a second input of the logic gate 140. The output of transmission gate 110-i is delayed compared to the second signal. In the exemplary embodiment of FIG. 1, where the logic gate 140 is a NAND gate, the second clock signal is obtained by applying the clock signal to an inverter 130 to obtain a reference signal (ref). The reference signal is applied to the second input of the logic gate 140.

As shown in FIG. 1, the output of the NAND gate 140, which is a digital pulse whose width is determined by its input signals, as described below, is applied to a low pass filter 150. In the exemplary embodiment of FIG. 1, the low pass filter 150 is embodied as a capacitor 160. Thus, if the clock signal is of sufficiently high frequency, the output, Vout, of the low pass filter is a DC voltage proportional to the width of the output of the NAND gate 140. The output, Vout, can be measured, for example, by an off-chip voltmeter, or by an analog-to-digital converter on the chip.

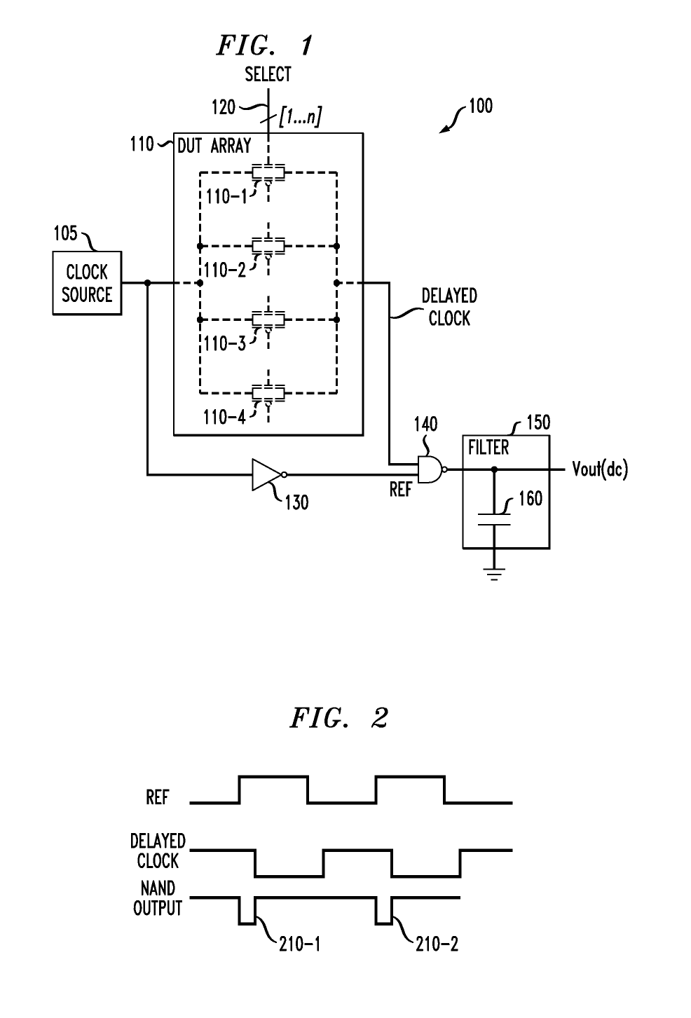

As discussed further below, the width of the output pulse of the logic gate 140 generally indicates a difference in arrival times of the signals at the two inputs. FIG. 2 illustrates the various signals shown in FIG. 1. As shown in FIG. 2, the output of the NAND gate 140 contains pulses 210-1, 210-2 that are present when the two inputs to the NAND gate 140 do not arrive at the same time. Thus, the width of pulses 210-1, 210-2 indicates a difference in arrival times of the Ref and Delayed Clock signals at the two inputs of the NAND gate 140. Thus, the present invention recognizes that the width of pulses 210-1, 211-2 indicates the delay through the selected transistor 110-i. In this manner, the present invention measures the source-to-drain delay through the combined nFET and pFET 110-i.

It is noted that while high frequency clock signals are applied continuously to the NAND gate 140, the width of pulses 210-1, 210-2 can be measured as a DC voltage. By selecting different DUTs 110-i in the array 110, different voltages, corresponding to different delays, will be recorded. The accuracy of the measurement using the exemplary circuit 100 of FIG. 1 is best when the clock signal is of sufficiently high frequency.

Other embodiments may use different logic gates 140, such as OR gates or exclusive OR gates (XORs) which have the property that their output pulse width depends on the timing differences between their input signals.

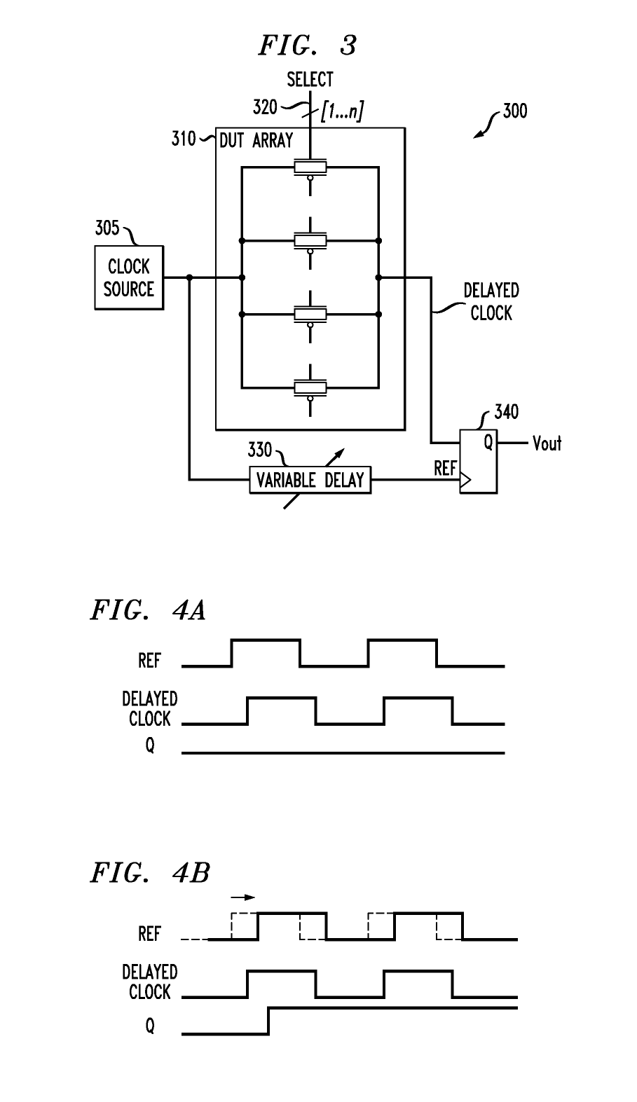

FIG. 3 illustrates a circuit 300 for measuring a delay through one or more transistors 310-1 through 310-4 in an array of transistors (collectively, referred to as array 310), in accordance with an alternate embodiment of the present invention. The exemplary circuit 300 comprises a selection circuit 320 for selecting one of the transistors 310-i to be active in the array 310, in a similar manner to the circuit 100 of FIG. 1.

In addition, the exemplary circuit 300 includes a latch 340. A clock signal source 305, such as an external clock source or an on-chip oscillator, applies a clock signal to the selected transistor 310-i that is selected by the selection circuit 320. As shown in FIG. 3, an output of the selected transistor 310-i is applied to a data input of the latch 340.

In addition, as shown in FIG. 3, a second clock signal, based on the clock signal, is applied to a clock input of the latch 340. In the exemplary embodiment of FIG. 3, the second clock signal is obtained by applying the clock signal to a variable delay circuit 330 to obtain a reference clock signal (Ref). The reference signal is applied to the clock input of the latch 340. The variable delay circuit 330 delays the signal to the clock input of the latch 340 by a known amount by using, for example, a delay chain.

The delay applied by the variable delay circuit 330 to the clock signal is adjusted in accordance with the embodiment of FIG. 3 until a transition is detected in an output, Q, of the latch 340. A transition in the output, Q, of the latch 340 generally indicates when the delay through the DUT 110-i and the variable delay circuit 330 are equal FIGS. 4A and 4B illustrates the various signals shown in FIG. 3. FIG. 4A illustrates the various signals shown in FIG. 3 at a time when the delay through the DUT 110-i is less than the delay through the variable delay circuit 330. As shown in FIG. 4A, if the delayed clock signal arrives after the Ref signal, a “0” is latched by the latch 340.

FIG. 4B illustrates the various signals shown in FIG. 3 at a time when the variable delay circuit 330 has been adjusted such that the delay through the DUT 110-i is equal to or greater than the delay of the variable delay circuit 330. As shown in FIG. 4B, if the Ref is retarded sufficiently, a “1” will be latched. Thus, the transition in the output, Q, of the latch 340 can be measured as a DC transition, for example, by an on-chip circuit. The process is repeated for each transistor in the DUT array 310. For each DUT 110-i selected, the delay is swept until a 0-to-1 transition is detected, and the value of the delay setting is recorded. Hence, the delay through each DUT 110-i is measured. Compared to the embodiment of FIG. 1, the embodiment of FIG. 3 does not require a high frequency clock signal to achieve high measurement accuracy

FIG. 5 illustrates a first alternative design 500 for the DUT array 110 of FIG. 1. As shown in FIG. 5, the exemplary DUT array 500 is embodied as a pass transistor array, comprising one or more FET transistors 510-1 through 510-N. The exemplary circuit 500 also comprises a selection circuit 520 for selecting one of the transistors 510-i to be active in the array 500, by asserting an appropriate select line signal. The select line signal can be derived, for example, from a finite state machine or a scan chain. The array 500 is a DUT (“Device Under Test”) array of n transmission gates. In this manner, the present invention measures the source-to-drain delay through a single FET 510-i.

FIG. 6 illustrates a second alternative design 600 for the DUT array 110 of FIG. 1. As shown in FIG. 6, the exemplary DUT array 600 comprises an array of transmission gates 610-1 through 610-N and inverters 630-1 through 630-N. In this array 600, in addition to the source-to-drain delay of each transmission gate 610-1 through 610-N, the delay from gate-to-output of the corresponding inverter 630-1 through 630-N is also measured. The transmission gates 610-1 through 610-N can be made large, to minimize delay variation due to threshold voltage variation of small devices.

FIG. 7 illustrates a third alternative design 700 for the DUT array 110 of FIG. I. As shown in FIG. 7, the array 700 comprises transmission gates 710-1 through 720-N and corresponding nFET transistors 730-1 through 730-N. Each transmission gate 710-1 through 720-N comprises an NFET transistor and a PFET transistor. In the embodiment of FIG. 7, the transmission gates 710-1 through 720-N serve as switches under control of the selection circuit 720. The array 700 also comprises a pull-up resistor 750. Thus, in addition to the source-to-drain delay through a given transmission gate 710-1 through 720-N, the present invention measures the delay from gate to drain of the corresponding FET 730-1 through 730-N. A similar structure can be made to test pFETs, where voltage polarities are appropriately changed, as would be apparent to a person of ordinary skill in the art. The transmission gates 710-1 through 710-N can be made large, to minimize delay variation due to threshold voltage variation of small devices.

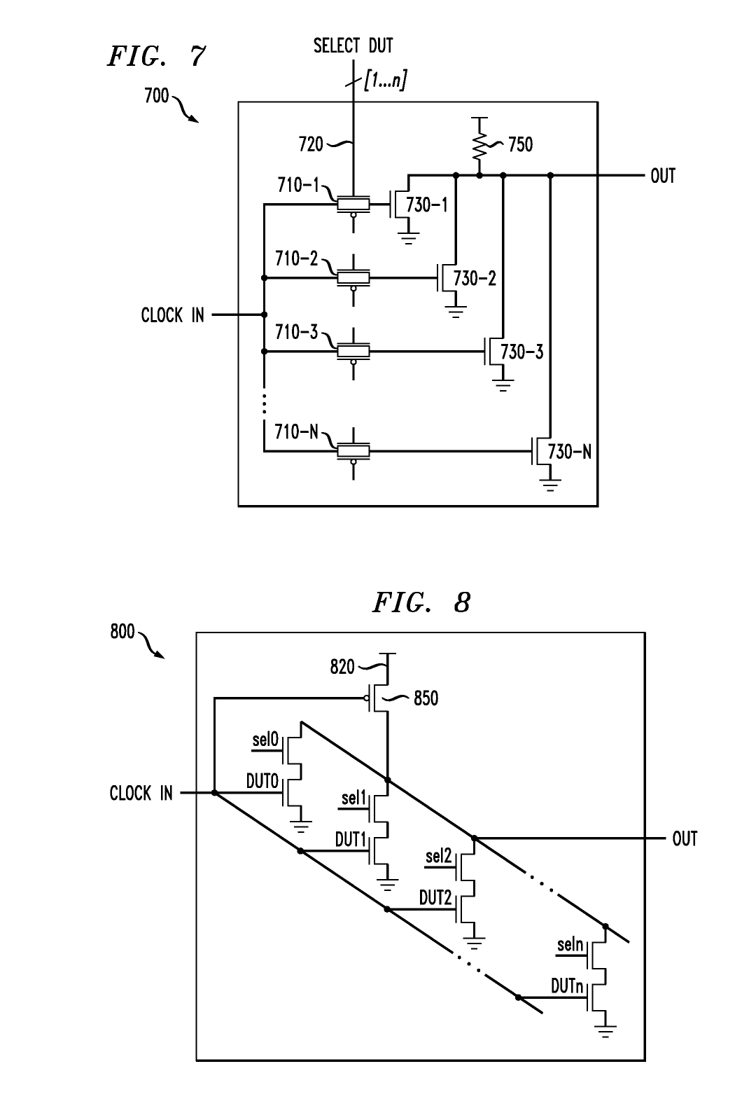

FIG. 8 illustrates another alternative design 800 for the DUT array 110 of FIG. 1. As shown in FIG. 8, the array 800 comprises a plurality of nFETs sel0-seln in an inverter configuration with a common pFET 850. The select nFETs sel0-seln are stacked with the nFETs under test DUT0 through DUTn. The configuration 800 of FIG. 8 may be less sensitive to the variation of the select devices. In addition, the configuration 800 uses a common pFET 850. Thus, only the variation of the delay of the selected nFET DUTi is measured. Generally, the nFETs under test DUT0 through DUTn are comparable to the DUTs of FIG. 7 and the selection nFETs sel0-seln are similar to the selection circuit of FIG. 5.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A circuit for measuring a delay through one or more transistors in an array of transistors, said circuit comprising:
a selection circuit for selecting one of said transistors in said array;
a logic gate having at least two inputs; and
a clock signal source for applying a clock signal to said selected transistor, wherein an output of said selected transistor is applied to a first input of said logic gate and wherein a second clock signal based on said clock signal is applied to a second input of said logic gate, and wherein an output of said logic gate indicates a difference in arrival times of said signals at said two inputs.

2. The circuit of claim 1, wherein said logic gate comprises a logic gate having an output pulse width that depends on timing differences between input signals to said logic gate.

3. The circuit of claim 1, further comprising a low pass filter at the output of the logic gate.

4. The circuit of claim 1, wherein the selection circuit asserts an appropriate select line signal.

5. The circuit of claim 1, wherein the selection circuit comprises an array of transmission gates.

6. The circuit of claim 1, further comprising a voltage measurement device to measure said output of said logic gate.

7. The circuit of claim 6, wherein said voltage measurement device comprises one or more of an off-chip voltmeter and an on-chip analog to d a converter.

8. The circuit of claim 1, wherein said array of transistors comprises one or more of a pass transistor array, an array of transmission gates and inverters, and an array of transmission gates and corresponding nFET transistors.

9. The circuit of claim 1, wherein the selection circuit comprises an array of selection nFET transistors and wherein said array of transistors comprises an array of nFET transistors.

10. The circuit of claim 1, wherein said circuit is embedded on an integrated circuit with said array of transistors to provide on-chip measurement of said delay.

11. The circuit of claim 1, wherein said delay is measured through a plurality of said transistors in said array to obtain a measurement of delay variation among said plurality of said transistors.

12. A circuit for measuring a delay through one or more transistors in an array of transistors, said circuit comprising:
a selection circuit for selecting one of said transistors in said array;
a latch having clock and data inputs;
a variable delay circuit; and
a clock signal source for applying a clock signal to said selected transistor and said variable delay circuit, wherein an output of said selected transistor is applied to a data input of said latch and wherein an output of said variable delay circuit is applied to a clock input of said latch, and wherein a delay applied by said variable delay circuit to said clock signal is adjusted until a predefined transition is detected at an output of said latch.

13. The circuit of claim 12, wherein the selection circuit asserts an appropriate select line signal.

14. The circuit of claim 12, wherein the selection circuit comprises an array of transmission gates.

15. The circuit of claim 10, further comprising means for measuring a binary value at said output of said latch.

16. The circuit of claim 12, wherein said array of transistors comprises one or more of a pass transistor array, an array of transmission gates and inverters, and an array of transmission gates and corresponding nFET transistors.

17. The circuit of claim 12, wherein the selection circuit comprises an array of selection nFET transistors and wherein said array of transistors comprises an array of nFET transistors.

18. The circuit of claim 12, wherein said circuit is embedded on an integrated circuit with said array of transistors to provide on-chip measurement of said delay.

19. The circuit of claim 12, wherein said delay is measured through a plurality of said transistors in said array to obtain a measurement of delay variation among said plurality of said transistors.

20. A method for measuring a delay through one or more transistors in an array of transistors, said method comprising:
selecting one of said transistors in said array; and
applying a clock signal to said selected transistor, wherein an output of said selected transistor is applied to a first input of a logic gate having at least two inputs and wherein a second clock signal based on said clock signal is applied to a second input of said logic gate, and wherein an output of said logic gate indicates a difference in arrival times of said signals at said two inputs.

21. The method of claim 20, wherein selecting step further comprises the step of asserting an appropriate select line signal.

22. The method of claim 20, further comprising the step of measuring said output of said logic gate.

23. A method for measuring a delay through one or more transistors in an array of transistors, said method comprising:
selecting one of said transistors in said array;
applying a clock signal to said selected transistor and a variable delay circuit;
applying an output of said selected transistor to a data input of a latch having a clock input and a data input;
applying an output of said variable delay circuit to a clock input of said latch; and
adjusting a delay applied by said variable delay circuit to said clock signal until a predefined transition is detected in an output of said latch.

24. The method of claim 23, wherein the selecting step asserts an appropriate select line signal.

25. The method of claim 23, further comprising the step of measuring said output of said latch.
